(19) United States
(12) Patent Application Publication
(10) Pub. No.: US 2026/0312592 A1
(43) Pub. Date: Oct. 8, 2026

(54) LOCK DETECTOR INCLUDING DIGITAL CALIBRATION

(71) Applicant: Samsung Electronics Co., Ltd., Suwon-si (KR)

(72) Inventors: Taeyeon KIM, Suwon-si (KR); Minseob LEE, Suwon-si (KR); Honggul HAN, Suwon-si (KR); Joonhee LEE, Suwon-si (KR); Ikkyun JO, Suwon-si (KR)

(73) Assignee: Samsung Electronics Co., Ltd., Suwon-si (KR)

(21) Appl. No.: 19/639,955

(22) Filed: Apr. 6, 2026

(30) Foreign Application Priority Data
Apr. 7, 2025 (KR) 10-2025-0044809

(51) Int. Cl. H03L 7/095; H03K 3/037; H03L 7/093

(52) U.S. Cl. CPC H03L 7/095; H03K 3/037; H03L 7/093

(57) ABSTRACT

A lock detector including a first digital-to-time converter (DTC) that delays a reference clock based on a first digital code to provide a first delayed clock; a second DTC that delays a target clock based on a second digital code to provide a second delayed clock; a phase difference detection circuit that obtains an error signal indicating a phase relationship between the first delayed clock and the second delayed clock; a calibration circuit that calibrates the first digital code to reduce a phase difference between the first delayed clock and the second delayed clock based on the error signal; and a lock detection circuit that provides a lock detection signal indicating whether the first delayed clock and the second delayed clock are within a set lock detection range.

### CROSS-REFERENCE TO RELATED APPLICATION(S)

This U.S. non-provisional application claims priority under 35 USC § 119 to Korean Patent Application No. 10-2025-0044809, filed on Apr. 7, 2025, in the Korean Intellectual Property Office, the disclosure of which is herein incorporated by reference in its entirety.

### BACKGROUND

The present disclosure relates to lock detectors, radio-frequency (RF) chips including a lock detector, and methods of determining lock detection.

A phase locked loop (PLL) locks a frequency of a clock to a desired frequency, and outputs or supplies a clock having the locked frequency. For example, a PLL continuously compares phases of a reference clock having a desired frequency and a target clock, and corrects a frequency of the target clock based on the comparison result. A state in which the target clock is synchronized with the reference clock may be referred to as a lock state, and a state in which a phase difference between the reference clock and the target clock is within a certain range may also be regarded as a lock state.

Due to environmental conditions such as process, voltage, and temperature (PVT), characteristics of components included in a PLL, or nonlinearities that may exist in circuits or devices in which the PLL is implemented, a phase difference corresponding to a variable offset may be present between the reference clock and the target clock. When an offset is present, the range of a phase difference (for example, lock detection range) that may be regarded as a lock state should be set to be larger than the offset in consideration of the offset.

### SUMMARY

The present disclosure provides a lock detector that improves the accuracy of lock detection, an RF chip including the lock detector, and a method of determining lock detection of a lock detector.

Some example embodiments of the present disclosure provide a lock detector that includes a first digital-to-time converter (DTC) that delays a reference clock based on a first digital code to provide a first delayed clock; a second DTC that delays a target clock based on a second digital code to provide a second delayed clock; a phase difference detection circuit that obtains an error signal indicating a phase relationship between the first delayed clock and the second delayed clock; a calibration circuit that calibrates the first digital code to reduce a phase difference between the first delayed clock and the second delayed clock based on the error signal; and a lock detection circuit that provides a lock detection signal indicating whether the first delayed clock and the second delayed clock are within a set lock detection range.

Some example embodiments of the present disclosure further provide a radio-frequency (RF) chip that includes a phase locked loop (PLL) circuit that detects a phase difference between a reference clock and a target clock, and adjusts a frequency of the target clock to reduce the phase difference; and a lock detector that provides a first delayed clock by delaying the reference clock based on a first digital code, provides a second delayed clock by delaying the target clock based on a second digital code, provides an error signal indicating a phase relationship between the first delayed clock and the second delayed clock, calibrates the first digital code to reduce a phase difference between the first delayed clock and the second delayed clock based on the error signal, and provides a lock detection signal indicating whether the first delayed clock and the second delayed clock are within a set lock detection range.

Some example embodiments still further provide a method of determining lock detection of a lock detector that includes delaying a reference clock based on a first digital code to provide a first delayed clock; delaying a target clock based on a second digital code to provide a second delayed clock; generating an error signal indicating a phase relationship between the first delayed clock and the second delayed clock; calibrating the first digital code to reduce a phase difference between the first delayed clock and the second delayed clock based on the error signal; and generating a lock detection signal indicating whether the first delayed clock and the second delayed clock are within a set lock detection range.

### BRIEF DESCRIPTION OF DRAWINGS

FIG. 1 is a circuit diagram of a lock detector according to some example embodiments.

FIG. 2 is a circuit diagram of a phase difference detection circuit according to some example embodiments.

FIG. 3 is a circuit diagram of a logic circuit according to some example embodiments.

FIG. 4 is a block diagram of a calibration circuit according to some example embodiments.

FIG. 5 is a circuit diagram of a lock detection circuit according to some example embodiments.

FIG. 6 is a block diagram of an RF chip according to some example embodiments.

FIG. 7 is a circuit diagram of a PLL circuit according to some example embodiments.

FIG. 8 is a diagram illustrating an example of the PLL circuit of FIG. 7.

FIG. 9 is a timing diagram illustrating a locking operation according to some example embodiments.

FIG. 10 is a timing diagram for each signal in a locking state according to some example embodiments.

FIG. 11 is a flowchart illustrating a method of operating a lock detector according to some example embodiments.

FIG. 12 is a flowchart illustrating a calibration method according to some example embodiments.

FIG. 13 is a diagram illustrating a wireless communication device according to some example embodiments.

### DETAILED DESCRIPTION

In the present disclosure, terms referring to electronic devices or RF-related components or products (for example, an antenna, an RF chip or an RF integrated circuit (RFIC), a power amplifier (PA), a low-noise amplifier (LNA), a mixer, an analog baseband (ABB) circuit, a frequency multiplier, or the like) are merely for ease of description, and the embodiments are not limited to these terms. For example, other terms having equivalent technical meanings may be used. For example, an RF chip may be replaced with an RF circuit or an RF module.

In the present disclosure, the coupling between Component A and Component B may include both physical and electrical connections therebetween.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

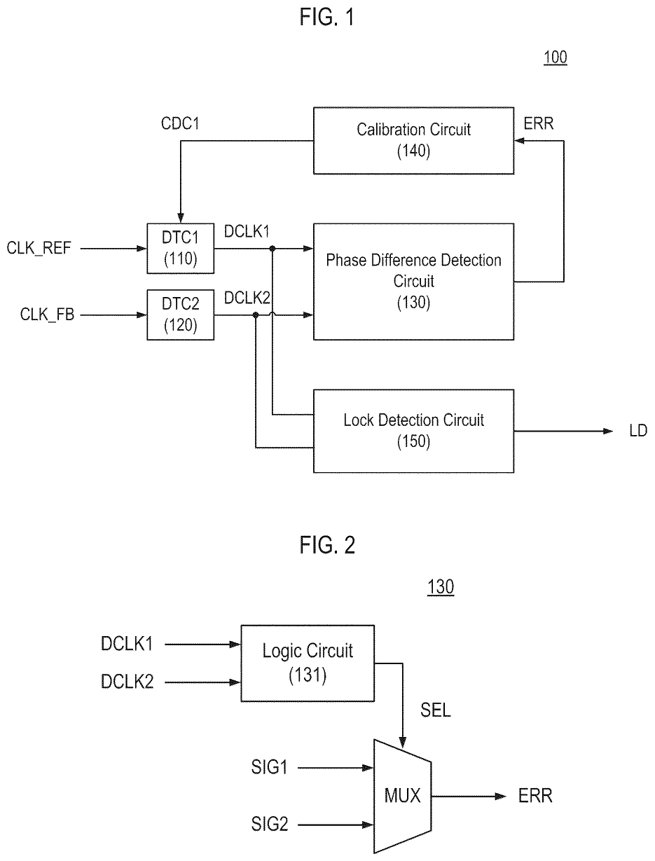

FIG. 1 is a circuit diagram of a lock detector according to some example embodiments.

Referring to FIG. 1, a lock detector 100 according to some example embodiments includes a first digital-to-time converter (DTC) 110, a second DTC 120, a phase difference detection circuit 130, a calibration circuit 140, and a lock detection circuit 150.

The first DTC 110 (e.g., DTC1) and the second DTC 120 (e.g., DTC2) may be configured to delay input signals based on digital codes. For example, output signals of the first DTC 110 and the second DTC 120 may be delayed by a delay time value corresponding to a digital code of input signals. In the present application, a digital code may have a size of N bits (where N is a positive integer), and each bit value that may be represented or defined by a combination of N bits may represent a delay time value.

The first DTC 110 may be configured to delay a reference clock CLK_REF based on a first digital code and obtain (e.g., provide) a first delayed clock DCLK1. For example, an input signal of the first DTC 110 may be a reference clock CLK_REF, and an output signal of the first DTC 110 may be a first delayed clock DCLK1 delayed by a delay time value indicated by the first digital code. For example, the reference clock CLK_REF may be a reference clock that may be a reference for phase locking in a phase locked loop (PLL).

The first digital code may be calibrated through the calibration circuit 140. A delay time value for the first delayed clock DCLK1 may be adjusted based on the calibration.

The second DTC 120 may be configured to delay a target clock CLK_FB based on a second digital code and obtain (e.g., provide) a second delayed clock DCLK2. For example, an input signal of the second DTC 120 may be a target clock CLK_FB, and an output signal of the second DTC 120 may be a second delayed clock DCLK2 delayed by a delay time value indicated by the second digital code. For example, the target clock CLK_FB may be a target clock (or a feedback clock or an output clock) that requires phase locking according to the reference clock in a PLL.

According to some example embodiments, the second digital code may have a desired (and/or alternatively predetermined) bit combination. For example, the delay time value indicated by the second digital code may be a desired (and/or alternatively predetermined) value. For example, the second digital code may be set to indicate an intermediate value among bit values represented as a bit combination or one of the values closest to the intermediate value.

The phase difference detection circuit 130 may be configured to obtain (e.g., provide or generate) an error signal ERR indicating a phase relationship between the first delayed clock DCLK1 output through the first DTC 110 and the second delayed clock DCLK2 output through the second DTC 120. For example, the phase difference detection circuit 130 may receive the first delayed clock DCLK1 and the second delayed clock DCLK2 from the first DTC 110 and the second DTC 120, and determine (or identify) a phase relationship between the first delayed clock DCLK1 and the second delayed clock DCLK2. The phase relationship indicates whether the first delayed clock DCLK1 has a phase leading or lagging behind the second delayed clock DCLK2.

According to some example embodiments, the phase difference detection circuit 130 may sample the first delayed clock DCLK1 based on the second delayed clock DCLK2, and determine the phase relationship based on a sampling result. For example, the phase difference detection circuit 130 may be configured to include a delay chain or delay stages for sampling. For example, the phase difference detection circuit 130 may include logic circuit(s) for phase relationship determination.

The error signal ERR may have a positive sign or a negative sign according to the phase relationship. For example, when the phase of the first delayed clock DCLK1 leads, the error signal ERR may have a positive sign, and when the phase of the first delayed clock DCLK1 lags, the error signal ERR may have a negative sign. For example, when the error signal ERR may be defined without an additional weight, the error signal ERR may be +1 or −1.

The calibration circuit 140 may be configured to calibrate the first digital code to significantly reduce a phase difference between the first delayed clock DCLK1 and the second delayed clock DCLK2 based on the error signal ERR output from the phase difference detection circuit 130. The calibration circuit 140 may perform digital calibration using the error signal ERR. For example, the calibration circuit 140 may be implemented with various hardware and/or software for digital calibration such as a digital signal processor (DSP), a field-programmable gate array (FPGA), an application-specific integrated chip (ASIC), or a microcontroller unit (MCU).

The error signal ERR may be used to determine the direction of calibration. For example, through the error signal ERR, a determination may be made whether to increase or decrease the delay time value indicated by the first digital code.

The calibration circuit 140 may provide the calibrated first digital code CDC1 to the first DTC 110 (see FIG. 1) through calibration. Through the calibrated first digital code CDC1, the delay time value of the first delayed clock DCLK1 may be adjusted to significantly reduce the phase difference between the first delayed clock DCLK1 and the second delayed clock DCLK2.

The first delayed clock DCLK1 and the second delayed clock DCLK2, whose phase difference is significantly reduced through calibration, may be provided to the lock detection circuit 150.

The lock detection circuit 150 may be configured to obtain (e.g., provide or generate) a lock detection signal LD indicating whether the first delayed clock DCLK1 and the second delayed clock DCLK2 may be within a set lock detection range. In the present application, the lock detection range may be defined as the range within which the phase of the target clock (for example, the target clock CLK_FB) is considered to be locked. A larger lock detection range means that a greater phase difference is allowed for the target clock. Therefore, even when the target clock is within the lock detection range, it may indicate that the actual phase noise of the target clock is high and/or the signal quality is degraded.

The lock detection signal LD may have different logical states depending on whether the phase difference between the first delayed clock DCLK1 and the second delayed clock DCLK2 is within the lock detection range. For example, when the lock detection signal LD is high, the phase difference may be within the lock detection range. Alternatively, when the lock detection signal LD is low, the phase difference may be outside the lock detection range.

According to the above-described embodiments, the phase relationship detection and calibration may significantly reduce the phase difference, which may be present between the reference clock and the target clock due to various factors (nonlinearity of the circuit, process, voltage, temperature (PVT)), during lock detection. Accordingly, lock detection may be performed on clocks (the first delayed clock DCLK1 and the second delayed clock DCLK2) whose phase difference is significantly reduced, so that the accuracy of lock detection may be improved.

FIG. 2 is a circuit diagram of a phase difference detection circuit according to some example embodiments.

Referring to FIG. 2, a phase difference detection circuit 130 according to some example embodiments may include a logic circuit 131 and a multiplexer MUX.

The logic circuit 131 may be configured to receive the first delayed clock DCLK1 and the second delayed clock DCLK2, and obtain a select signal SEL based on the first delayed clock DCLK1 and the second delayed clock DCLK2. According to some example embodiments, the logic circuit 131 may receive the first delayed clock DCLK1 and the second delayed clock DCLK2 from the above-described first and second DTCs 110 of FIG. 1. The select signal SEL may be used to select one of input signals in the multiplexer (MUX). The select signal SEL may have a logic level based on the phase relationship between the first delayed clock DCLK1 and the second delayed clock DCLK2.

According to some example embodiments, the logic circuit 131 may obtain a select signal SEL having a logical high state based on the phase of the first delayed clock DCLK1 leading the second delayed clock DCLK2. Alternatively, the logic circuit 131 may obtain a select signal SEL having a logical low state based on the phase of the first delayed clock DCLK1 lagging behind the second delayed clock DCLK2.

According to some example embodiments, the logic circuit 131 may include a single flip-flop. An input signal of the flip-flop may be the first delayed clock DCLK1, and a clock for sampling the flip-flop may be the second delayed clock DCLK2. For example, when the flip-flop may be implemented in an edge triggering manner, the flip-flop may sample the first delayed clock DCLK1 at a rising edge or a falling edge of the second delayed clock DCLK2, based on the second delayed clock DCLK2. The first delayed clock DCLK1 may be delayed based on sampling. The select signal SEL may correspond to an output of a first flip-flop FF1.

A multiplexer MUX may be configured to receive the select signal SEL from the logic circuit 131, and select the sign (e.g., positive or negative) of the error signal ERR according to the select signal SEL. Input signals of the multiplexer MUX may be a first sign signal SIG1 and a second sign signal SIG2. For example, the first sign signal SIG1 may be +1, and the second sign signal SIG2 may be −1.

For example, when the select signal SEL is high, the multiplexer MUX may output the first sign signal SIG1 as the error signal ERR. When the select signal SEL is low, the multiplexer MUX may output the second sign signal SIG2 as the error signal ERR.

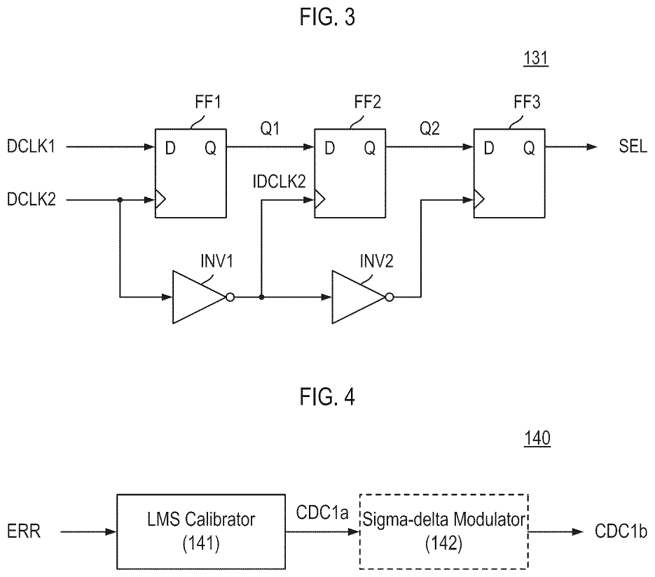

FIG. 3 is a circuit diagram of a logic circuit according to some example embodiments.

Referring to FIG. 3, a logic circuit 131 according to some example embodiments may include a first flip-flop FF1, a first inverter INV1, a second flip-flop FF2, a second inverter INV2, and a third flip-flop FF3.

An input signal of the first flip-flop FF1 may be the first delayed clock DCLK1, and a clock for sampling may be the second delayed clock DCLK2. The first flip-flop FF1 may sample the first delayed clock DCLK1 based on the second delayed clock DCLK2. An output of the first flip-flop FF1 may be a first sampled signal Q1 sampled from the first delayed clock DCLK1 based on the second delayed clock DCLK2.

The first inverter INV1 may be configured to invert a phase of the second delayed clock DCLK2. The phase-inverted second delayed clock IDCLK2 may be provided to a clock pin of the second flip-flop FF2.

An input signal of the second flip-flop FF2 may be a first sampled signal Q1, and a clock for sampling may be an inverted second delayed clock IDCLK2 corresponding to an output of the first inverter INV1. The second flip-flop FF2 may sample an output of the first flip-flop FF1 based on an output of the first inverter INV1. An output of the second flip-flop FF2 may be a second sampled signal Q2 sampled from the first sampled signal Q1 based on the inverted second delayed clock IDCLK2.

The second inverter INV2 may be configured to invert a phase of an output of the first inverter INV1. For example, an output of the second inverter INV2 may have the same phase as the second delayed clock DCLK2. An output of the second inverter INV2 may be provided to a clock pin of the third flip-flop FF3.

An input signal of the third flip-flop FF3 may be the second sampled signal Q2, and a clock for sampling may be an output of the second inverter INV2. The third flip-flop FF3 may sample an output of the second flip-flop FF2 based on an output of the second inverter INV2. An output of the third flip-flop FF3 may be a signal sampled from the second sampled signal Q2 based on an output of the second inverter INV2. For example, the select signal SEL may correspond to an output of the third flip-flop FF3.

According to the above-described embodiments, the logic circuit 131 may be configured in the form of a delay chain in which continuous flip-flops are connected in series, limiting and/or preventing metastability (where metastability refers to a phenomenon in which an output of a digital circuit remains in an uncertain state for a certain period of time without stabilizing in any logic state).

It will be understood that the logic circuit 131 according to some example embodiments is not limited to FIG. 3, and may be configured with a combination of various digital circuits configured to indicate a phase relationship between the first delayed clock DCLK1 and the second delayed clock DCLK2, or may be configured in various types of delay chains configured to limit and/or prevent metastability.

FIG. 4 may be a block diagram of a calibration circuit according to some example embodiments.

Referring to FIG. 4, a calibration circuit 140 according to some example embodiments may include a least mean square (LMS) calibrator 141. According to some example embodiments, the calibration circuit 140 may additionally include a sigma-delta modulator 142.

The LMS calibrator 141 may be configured to calibrate the first digital code based on an LMS algorithm. The LMS algorithm may calibrate the first digital code to significantly reduce a phase difference between the first delayed clock DCLK1 and the second delayed clock DCLK2.

For example, the LMS algorithm may calculate an output value based on an arbitrary point in time (for example, n, a positive integer) and calculate an error based on the calculated output value and a target value. The error may be distinct from the error signal ERR and may be defined as a difference between the output value and the target value. For example, the output value may be defined as a cumulative product of a bit value corresponding to the first digital code up to an arbitrary point in time and a coefficient (or weight). For example, the target value may be a bit value corresponding to the first digital code when the phase difference between the first delayed clock DCLK1 and the second delayed clock DCLK2 are significantly reduced. The LMS algorithm may update coefficients corresponding to arbitrary points in time to significantly reduce the phase difference.

According to some example embodiments, the LMS algorithm may determine the sign of a weight defined for the first digital code based on the sign of the error signal ERR, and may significantly reduce the error defined for the first digital code based on the weight. For example, when the sign of the weight may be positive, the first digital code may be calibrated in an increasing direction. Alternatively, when the sign of the weight may be negative, the first digital code may be calibrated in a decreasing direction.

A calibrated first digital code CDC1a may be output through the LMS calibrator 141. According to some example embodiments, when the calibration circuit 140 includes only the LMS calibrator 141, the calibrated first digital code CDC1a may be directly provided to the first DTC 110 (see FIG. 1).

The sigma-delta modulator 142 may perform sigma-delta modulation on the first digital code CDC1a calibrated through the LMS algorithm.

The sigma-delta modulation may quantize a plurality of bits included in the calibrated first digital code CDC1a into remaining bits, excluding at least one bit corresponding to fractional value information among the plurality of bits. For example, at least one bit in the plurality of bits may include fractional value information through the LMS algorithm. For example, when a bit value of the calibrated first digital code CDC1a is 100.5, fractional value information corresponding to 0.5 may be included in at least one bit. The sigma-delta modulator 142 may change the calibrated first digital code CDC1a over several cycles among N integers (where N is a positive integer) defined to be close to 100.5, through sigma-delta modulation.

Accordingly, the first digital code CDC1b calibrated through the sigma-delta modulation may include the remaining information (for example, integer value information) excluding the fractional value information.

The sigma-delta modulator 142 may provide the calibrated first digital code CDC1b to the first DTC 110 (see FIG. 1).

According to the above-described embodiments, the calibration circuit 140 may compensate for a phase difference (for example, offset) between the first delayed clock DCLK1 and the second delayed clock DCLK2, varying in real time through digital calibration, to improve the accuracy of lock detection.

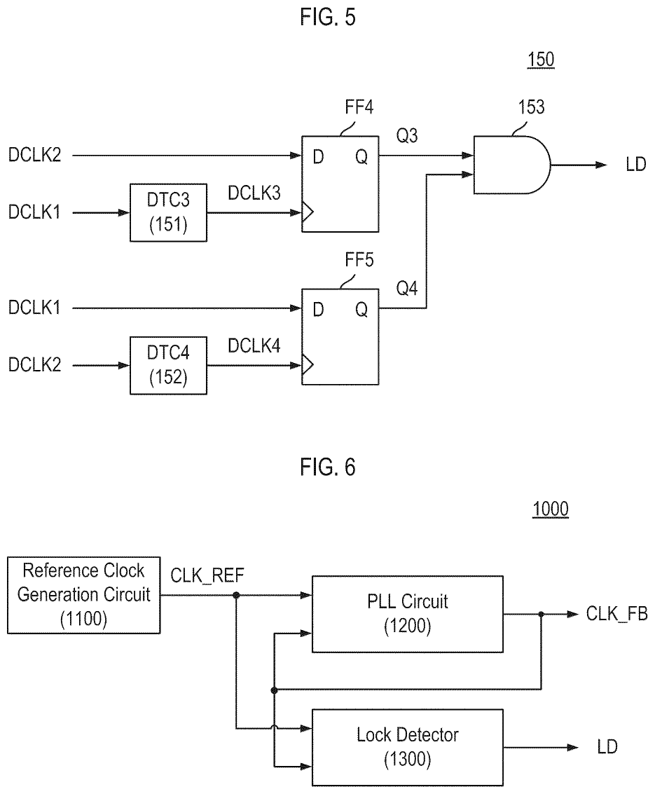

FIG. 5 is a circuit diagram of a lock detection circuit according to some example embodiments.

Referring to FIG. 5, a lock detection circuit 150 according to some example embodiments may include a third DTC 151, a fourth DTC 152, a fourth flip-flop FF4, a fifth flip-flop FF5, and an AND gate 153.

The third DTC 151 may be configured to delay the first delayed clock DCLK1 based on a third digital code and obtain a third delayed clock DCLK3. For example, an input signal of the third DTC 151 may be the first delayed clock DCLK1, and an output signal of the third DTC 151 may be a third delayed clock DCLK3 delayed by a delay time value indicated by the third digital code.

The fourth DTC 152 may be configured to delay the second delayed clock DCLK2 based on a fourth digital code and obtain a fourth delayed clock DCLK4. For example, an input signal of the fourth DTC 152 may be the second delayed clock DCLK2, and an output signal of the fourth DTC 152 may be a fourth delayed clock DCLK4 delayed by a delay time value indicated by the fourth digital code.

According to some example embodiments, the above-described third and fourth digital codes may have desired (and/or alternatively predetermined) bit combinations. For example, delay time values indicated by the third digital code and the fourth digital code may be desired (and/or alternatively predetermined) values. The third digital code and the fourth digital code may be set identically or differently.

The fourth flip-flop FF4 may be configured to sample the second delayed clock DCLK2 based on the third delayed clock DCLK3.

An input signal of the fourth flip-flop FF4 may be the second delayed clock DCLK2, and a clock for sampling may be the third delayed clock DCLK3. The fourth flip-flop FF4 samples the second delayed clock DCLK2 based on the third delayed clock DCLK3. An output of the fourth flip-flop FF4 may be a third sampled signal Q3 sampled from the second delayed clock DCLK2 based on the third delayed clock DCLK3.

An input signal of the fifth flip-flop FF5 may be the first delayed clock DCLK1, and a clock for sampling may be the fourth delayed clock DCLK4. The fifth flip-flop FF5 may be configured to sample the first delayed clock DCLK1 based on the fourth delayed clock DCLK4. An output of the fifth flip-flop FF5 may be a fourth sampled signal Q4 sampled from the first delayed clock DCLK1 based on the fourth delayed clock DCLK4.

The AND gate 153 may be configured to output a lock detection signal LD based on an AND operation on an output of the first flip-flop FF1 and an output of the second flip-flop FF2 (for example, the third sampled signal Q3 and the fourth sampled signal Q4). When both the third sampled signal Q3 and the fourth sampled signal Q4 are high, the lock detection signal LD may also be high. The target clock (for example, target clock CLK_FB) may be considered to be locked.

The lock detection range may be set based on at least one of the third digital code or the fourth digital code. The greater the bit value (for example, the delay time value) represented by the third digital code and/or the fourth digital code is set, the wider the lock detection range may be.

According to the above-described embodiments, the phase difference between the first delayed clock DCLK1 and the second delayed clock DCLK2 provided to the lock detection circuit 150 may be significantly reduced through calibration. Accordingly, even when the lock detection range is not set larger than an offset that may be present between the reference clock and the target clock, lock detection may be accurate and reliable.

FIG. 6 is a block diagram of an RF chip according to some example embodiments. Hereinafter, detailed descriptions of components overlapping with those described above will be omitted to avoid redundancy.

Referring to FIG. 6, an RF chip 1000 according to some example embodiments may include a reference clock generation circuit 1100, a PLL circuit 1200, and a lock detector 1300.

The reference clock generation circuit 1100 may be configured to generate and output a reference clock CLK_REF to be used in the PLL circuit 1200. For example, the reference clock generation circuit 1100 may include an oscillator (for example, a crystal oscillator, or the like) and/or another type of circuit for oscillation operation to generate a reference clock CLK_REF having a specific reference frequency. The reference clock generation circuit 1100 may provide the generated reference clock CLK_REF to the PLL circuit 1200.

The PLL circuit 1200 may be configured to detect a phase difference between the reference clock CLK_REF and the target clock CLK_FB and adjust a frequency of the target clock CLK_FB to significantly reduce the phase difference. The target clock CLK_FB may be provided as a local oscillator signal to an element requiring a local oscillator signal, such as a mixer or the like.

According to various embodiments, the PLL circuit 1200 may include an analog PLL (or linear PLL) including a charge pump-based PLL, a digital PLL, a fractional PLL or an injection-locked PLL, or the like.

According to some example embodiments, when the PLL circuit 1200 is configured based on a charge pump, an imbalance may occur in charge pump currents (pull-up current and pull-down current) due to mismatch or nonlinearity of transistors inside the charge pump. The imbalance may cause an offset between the reference clock CLK_REF and the target clock CLK_FB.

The lock detector 1300 may be configured to obtain a lock detection signal LD indicating whether the target clock CLK_FB may be within a lock detection range. The lock detector 1300 may be configured according to the above-described embodiments (see FIG. 1 and FIG. 5).

According to some example embodiments, the lock detector 1300 may obtain a first delayed clock DCLK1 by delaying a reference clock CLK_REF based on a first digital code, and obtain a second delayed clock DCLK2 by delaying a target clock CLK_FB based on a second digital code. The lock detector 1300 may obtain an error signal ERR indicating a phase relationship between the first delayed clock DCLK1 and the second delayed clock DCLK2, and calibrate the first digital code to significantly reduce a phase difference between the first delayed clock DCLK1 and the delayed target clock CLK_FB based on the error signal ERR. The lock detector 1300 may obtain a lock detection signal LD indicating whether the first delayed clock DCLK1 and the second delayed clock DCLK2 is within a set lock detection range.

A phase difference between the first delayed clock DCLK1 and the second delayed clock DCLK2 (for example, an offset caused by an imbalance in the charge pump current when the PLL circuit 1200 is a charge pump-based PLL) may be significantly reduced through the lock detector 1300. Accordingly, the lock detection range may be set to be narrower, and the target clock CLK_FB, having smaller phase noise and higher quality, may be considered to be within the lock detection range due to the lock detection range set to be narrower.

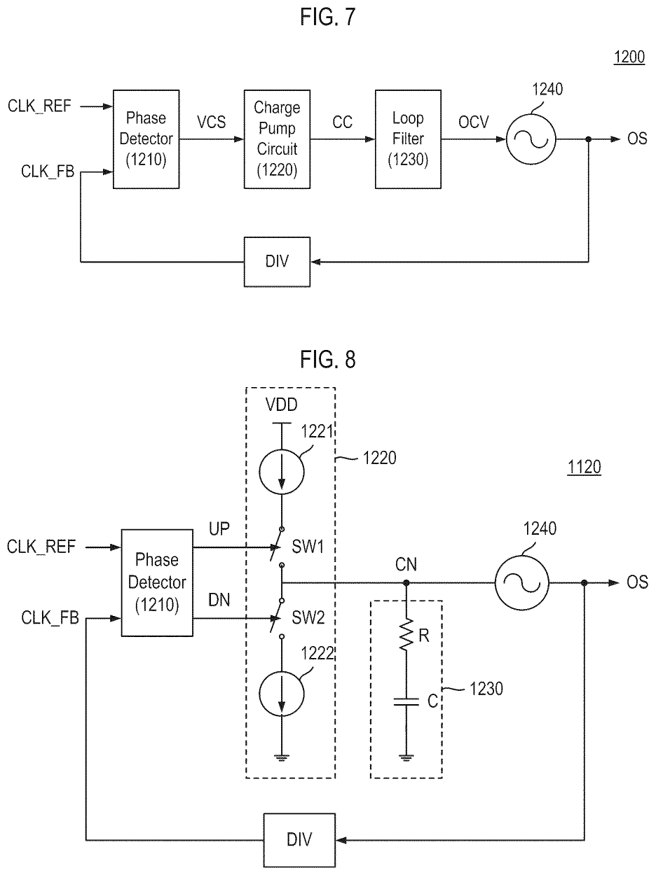

FIG. 7 is a circuit diagram of a PLL circuit according to some example embodiments.

Referring to FIG. 7, a PLL circuit 1200 according to some example embodiments may be implemented as a charge pump-based PLL, and may include a phase detection circuit 1210, a charge pump circuit 1220, a loop filter 1230, a voltage-controlled oscillator 1240, and a divider circuit DIV.

The phase detection circuit 1210 or phase detector may be configured to obtain a voltage control signal VCS corresponding to a phase difference between the reference clock CLK_REF and the target clock CLK_FB. According to some example embodiments, the phase detection circuit 1210 may detect a phase difference between the reference clock CLK_REF and the target clock CLK_FB based on sampling, and obtain and output a pulse-shaped voltage control signal VCS indicating the detected phase difference.

For example, the voltage control signal VCS may have a high level and a low level.

The charge pump circuit 1220 may generate a control current CC corresponding to the voltage control signal VCS provided from the phase detection circuit 1210. The loop filter 1230 may integrate the control current CC to generate an oscillation control voltage OCV. The voltage-controlled oscillator 1240 obtains and outputs an oscillation signal OS having a specific frequency in response to the oscillation control voltage OCV.

A frequency divider may divide the frequency of the oscillation signal OS output from the voltage-controlled oscillator 1240 and output a signal having the divided frequency as the target clock CLK_FB.

FIG. 8 is a diagram illustrating an example of the PLL circuit of FIG. 7.

Referring to FIG. 8, a phase detection circuit 1210 according to some example embodiments outputs a voltage control signal indicating a phase difference.

The charge pump circuit 1220 may be configured to adjust a voltage of a control node CN based on the voltage control signal provided from the phase detection circuit 1210. A charge pump circuit 1220 according to some example embodiments may include a first current source 1221, a first switch SW1, a second current source 1222, and a second switch SW2.

The first current source 1221 may be connected to a power supply voltage VDD, and may provide current to a control node CN based on an operation of the first switch SW1. The first switch SW1 may be turned on or off based on the voltage control signal. For example, when the voltage control signal is at a high level UP, it may be turned on. As the first switch SW1 is turned on, a voltage at the control node CN may be pulled up (for example, may rise).

The second current source 1222 may be grounded, and may pull down the voltage at the control node CN based on an operation of the second switch SW2. The second switch SW2 may be turned on or off based on the voltage control signal. For example, when the voltage control signal is at a low level DN, it may be turned on. As the second switch SW2 is turned on, the voltage at the control node CN may be pulled down (for example, may drop).

The loop filter 1230 may be coupled to the control node CN. According to some example embodiments, the loop filter 1230 may include a resistor R coupled to the control node CN, and a capacitor C having one end coupled to the resistor R and another end coupled to ground. The resistor R and the capacitor C may filter high-frequency components with respect to the control node CN. The capacitor C may charge and discharge electric charges to vary the voltage at the control node CN based on pull-up or pull-down.

The loop filter 1230 may be configured as an active loop filter instead of the passive loop filter according to the above-described embodiments.

The voltage-controlled oscillator 1240 may be coupled to the control node CN, and may be configured to obtain an oscillation signal OS based on the voltage at the control node CN. The divider circuit DIV may be configured to obtain the target clock CLK_FB based on distributing (e.g., dividing) a frequency of the oscillation signal OS.

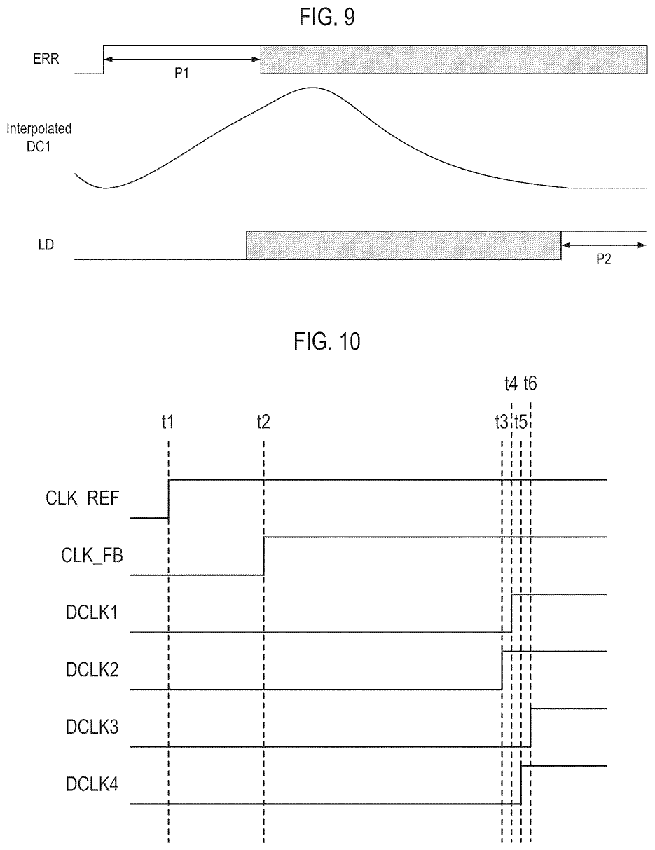

FIG. 9 is a timing diagram illustrating a locking operation of the RF chip 1000 of FIG. 6 for example, according to some example embodiments.

Referring to FIG. 9, an error signal ERR, a first digital code DC1, and a lock detection signal LD according to the above-described embodiments may be illustrated. For brevity, a waveform of the first digital code DC1 in FIG. 9 may be illustrated based on an interpolated waveform.

In a first period P1, the error signal ERR remains high. In the initial stage, a phase difference may be present between the reference clock and the target clock until the phase is locked through the PLL circuit according to the above-described embodiments. Accordingly, the error signal ERR determined from the first delayed clock and the second delayed clock also remains high until the phase is corrected.

The PLL circuit may continuously operate to correct the phase difference between the reference clock and the target clock. As the phase difference is corrected to some extent, the PLL circuit may vary the error signal ERR and the lock detection signal LD between logic high and logic low. The first digital code DC1 may be continuously corrected through the calibration circuit and then may converge to a certain value. In a second period P2, the first digital code DC1 may converge to a certain value, which means that the error signal ERR exhibits an average value close to 0. For example, the phases of the first delayed clock and the second delayed clock may become substantially identical on average.

Accordingly, the lock detection signal LD may indicate a logic high in the second period P2 to indicate that the first delayed clock and the second delayed clock are within the lock detection range.

The phase of the error signal ERR of FIG. 9 is only an example, and some example embodiments are not limited to FIG. 9. For example, the error signal ERR before phase locking may remain low. For example, the lock detection signal LD may indicate a logic high based on phase locking, and the error signal ERR may have an average value close to 0 after the phase locking, regardless of the logical level before phase locking (regardless whether the logical level is high or low).

FIG. 10 is a timing diagram by signal in a locking state according to some example embodiments.

Referring to FIG. 10, a phase difference (for example, offset) of t1 to t2 exists between the reference clock CLK_REF and the target clock CLK_FB. As described above, in spite of the locking through the PLL circuit, the offset may exist due to various environmental factors including PVT.

According to the above-described embodiments, the first delayed clock DCLK1 and the second delayed clock DCLK2 may be calibrated to significantly reduce a phase difference therebetween. The phase difference may be zero, or there may be a phase difference as small as t3 to t4, which is significantly smaller than t1 to t2, as illustrated in FIG. 10. The phase difference of t3 to t4 may be a resolution value of the first DTC and/or the first digital code according to the above-described embodiments. The resolution value may refer to a time interval between two consecutive bit combinations among bit combinations of the first digital code. For example, when the size of the first digital code is N bits and a maximum delay time value of the first digital code is K (where K is a real number greater than 0), the resolution value may be defined as K/2N.

The lock detection range may be set based on a phase difference between the first delayed clock DCLK1 and the third delayed clock DCLK3 (for example, a period t4 to t6) and a phase difference between the second delayed clock DCLK2 and the fourth delayed clock DCLK4 (for example, a period t3 to t5). When the lock detection range is set based on the reference clock CLK_REF and the target clock CLK_FB, the lock detection range inevitably should be set to be larger than the offset t1 to t2. When the lock detection range is set based on the first delayed clock DCLK1 and the second delayed clock DCLK2 according to the above-described embodiments, the lock detection may be accurate and reliable even if the lock detection range is set to be larger than the phase difference of t3 to t4 (for example, the resolution value of the first DTC and/or the first digital code).

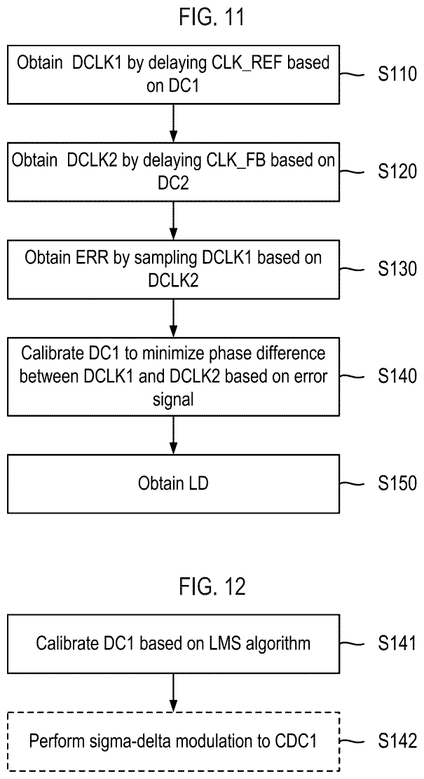

FIG. 11 is a flowchart illustrating a method of operating a lock detector according to some example embodiments.

Referring to FIG. 11, in operation S110, a lock detector may obtain a first delayed clock DCLK1 by delaying a reference clock CLK_REF based on a first digital code. The first delayed clock DCLK1 may be a signal delayed by a delay time value indicated by the first digital code.

In operation S120, the lock detector may obtain a second delayed clock DCLK2 by delaying a target clock CLK_FB based on a second digital code. The second delayed clock DCLK2 may be a signal delayed by a delay time value indicated by the second digital code. According to some example embodiments, the second digital code may be desired (and/or alternatively predetermined) and fixed to a specific bit combination (for example, a bit combination indicating either an intermediate value among bit values represented as bit combinations, or one of the values closest to the intermediate value).

In operation S130, the lock detector may obtain an error signal ERR indicating a phase relationship between the first delayed clock DCLK1 and the second delayed clock DCLK2. For example, the error signal ERR may be obtained by sampling the first delayed clock DCLK1 based on the second delayed clock DCLK2.

In operation S140, the lock detector may calibrate the first digital code to significantly reduce a phase difference between the first delayed clock DCLK1 and the second delayed clock DCLK2 based on the error signal ERR. Operation S140 may be repeatedly performed until the phase difference is significantly reduced. The calibrated first digital code may be used again in operation S110 to obtain the first delayed clock DCLK1.

In operation S150, the lock detector may obtain a lock detection signal LD indicating whether the first delayed clock DCLK1 and the second delayed clock DCLK2 are within a set lock detection range. Through operations S110 to S140, the phase difference between the first delayed clock DCLK1 and the second delayed clock DCLK2 may be significantly reduced. Accordingly, even when the lock detection range is set to be relatively small (for example, set to be greater than or equal to a resolution value of the first DTC 110), a lock detection signal LD indicating a logical high may be obtained in operation S150.

FIG. 12 is a flowchart illustrating a calibration method according to some example embodiments.

Referring to FIG. 12, in operation S141, the lock detector calibrates a first digital code DC1 based on an LMS algorithm. For example, the LMS algorithm may determine a sign of a weight defined for the first digital code DC1 based on a sign of an error signal ERR, and may significantly reduce an error defined for the first digital code DC1 based on the weight.

According to some example embodiments, the LMS algorithm may include an operation of accumulating the error signal ERR, an operation of accumulating a product of a coefficient having a sign determined based on the sign of the error signal ERR and a bit value corresponding to the first digital code DC1, and an operation of updating the coefficient.

In operation S142, the lock detector may perform sigma-delta modulation on the first digital code CDC1 calibrated through the LMS algorithm. For example, the sigma-delta modulation may quantize a plurality of bits included in the calibrated first digital code CDC1 into the remaining bits excluding at least one bit corresponding to fractional value information among the plurality of bits.

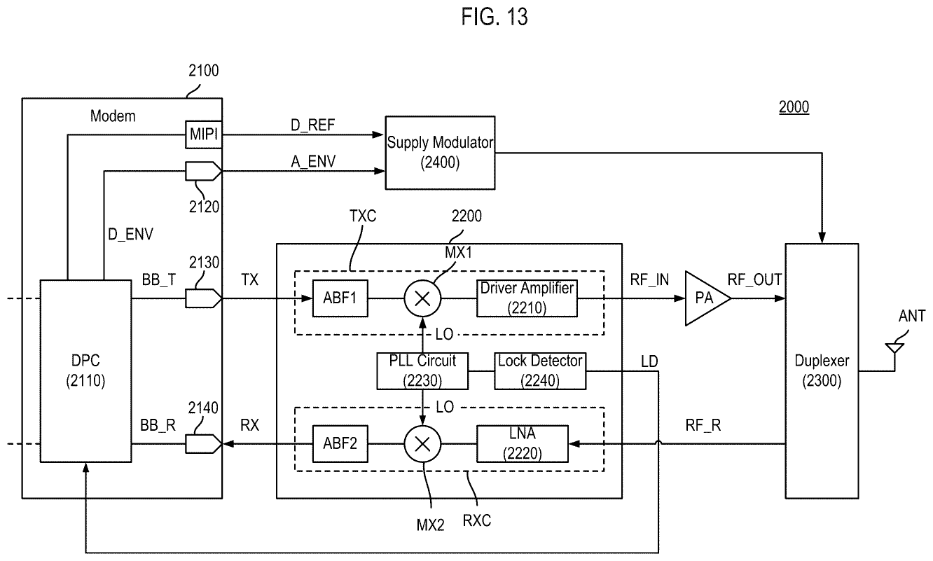

FIG. 13 is a diagram illustrating a wireless communication device according to some example embodiments.

Referring to FIG. 13, a wireless communication device 2000 may include a modem 2100, an RF chip 2200, a duplexer 2300, a power modulator 2400, and an antenna ANT.

The modem 2100 may include a digital processing circuit 2110, a first digital-to-analog converter (DAC) 2120, a second DAC 2130, an analog to digital converter ADC 2140, and a mobile industry processor interface (MIPI). The modem 2100 may process a baseband signal BB_T including information to be transmitted through the digital processing circuit 2110 (including, for example, an I-signal and a Q-signal) based on various communication schemes. The modem 2100 may process a received baseband signal BB_R through the digital processing circuit 2110 based on various communication schemes.

For example, the modem 2100 may process a signal to be transmitted or a received signal based on communication schemes such as orthogonal frequency division multiplexing (OFDM), orthogonal frequency division multiple access (OFDMA), wideband code multiple access (WCDMA), high speed packet access+ (HSPA+), or the like. In some example embodiments, the modem 2100 may process a baseband signal BB_T or BB_R based on various types of communication schemes (for example, various communication schemes to which technology for modulating or demodulating amplitude and frequency of a baseband signal BB_T or BB_R is applied).

According to some example embodiments, the modem 2100 may extract an envelope of the baseband signal BB_T through the digital transmission processor 2110 and generate a digital envelope signal D_ENV based on the extracted envelope.

According to some example embodiments, the modem 100 may generate an average power signal D_REF based on an average power tracking (APT) table (for example, an APT table) stored in a memory. In the APT table, information of a power supply voltage of the power amplifier PA according to an expected output power (or transmission power) of the antenna ANT may be stored, and average power signal information corresponding to the power supply voltage of the power amplifier PA may be stored. Accordingly, when the expected output power of the antenna ANT is determined, the modem 100 may generate the average power signal D_REF using the APT table and may apply the generated average power signal D_REF to the supply modulator 300 as a reference voltage signal.

The digital processing circuit 2110 may perform various processing operations on a baseband signal in a digital domain.

For example, the digital processing circuit 2110 may perform the above-described average power signal generation, envelope extraction, digital envelope signal generation, crest factor reduction (CFR), shaping function (SF), digital pre-distortion (DPD), delay compensation, or the like.

CFR may reduce a peak-to average power ratio (PAPR) of a communication signal (for example, the baseband signal BB_T). SF may transform the digital envelope signal D_ENV to improve the efficiency and linearity of the power amplifier PA. DPD may compensate for and linearize distortion of the power amplifier PA in a digital region. The delay compensation operation may compensate for a delay of a digital envelope signal D_ENV or a baseband signal BB_T.

The digital processing circuit 2110 may output a digital envelope signal D_ENV and a baseband signal BB_T. The digital envelope signal D_ENV may be converted into an analog envelope signal A_ENV through the first DAC 2120 and provided to the power modulator 2400, and the baseband signal BB_T may be converted into a transmit signal TX through the second DAC 2130 and provided to the transmit circuit TXC.

Although not illustrated in the drawings, the digital processing circuit 2110 may further include internal components configured to process the above-described operations (for example, baseband signal processing, envelope extraction, digital envelope signal generation, or the like).

At least one second DAC (2130) and at least one ADC (2140) may be provided. The modem 2100 may convert the baseband signal BB_T into analog using the second DAC 2130 to generate a transmit signal TX. In some example embodiments, the modem 2100 may receive a received signal RX, an analog signal, from the RF chip 2200. In some example embodiments, the modem 2100 may digitally convert the received signal RX through the ADC 2140 provided therein to extract a baseband signal BB_R, a digital signal. For example, the received signal RX may be a differential signal including a positive signal and a negative signal.

The RF chip 2200 may generate an RF input signal RF_IN by performing frequency up-conversion on a transmit signal TX, or generate a received signal RX by performing frequency down-conversion on an RF received signal RF_R. For example, the RF chip 2200 may include a transmit circuit TXC for frequency up-conversion, a receive circuit RXC for frequency down-conversion, a local oscillator LO in PLL circuit 2230, and a lock detector 2240.

The transmit circuit TXC may include a first analog baseband filter ABF1, a first mixer MX1, and a driver amplifier 2210. For example, the first analog baseband filter ABF1 may include a low-pass filter.

The baseband filter ABF1 may filter the transmit signal TX received from the modem 2100, and provide the filtered transmit signal TX to the first mixer MX1. For example, the baseband filter ABF1 may filter the baseband signal. The first mixer MX1 may perform frequency up-conversion to convert the frequency of the transmit signal TX from a baseband to a high-frequency band through a frequency signal provided by a local oscillator LO. The frequency up-conversion may enable the transmit signal TX to be provided as an RF input signal RF_IN to the driver amplifier 2210, which may perform primary amplification and provide the amplified signal to the power amplifier PA.

The power amplifier PA may receive a direct current DC voltage or a variable power supply voltage for example, dynamically varying output voltage, and may secondarily amplify the power of the RF input signal RF_IN based on the received power supply voltage to generate an RF output signal RF_OUT. In some example embodiments, the power amplifier PA may provide the generated RF output signal RF_OUT to the duplexer 2300.

The receive circuit RXC may include a second analog baseband filter ABF2, a second mixer MX2, and a low-noise amplifier LNA 2220. For example, the second analog baseband filter ABF2 may include a low pass filter.

The LNA 2220 may amplify the RF receive signal RF_R received through the duplexer 2300 and provide the amplified RF receive signal RF_R to the second mixer MX2. The second mixer MX2 may perform frequency down-conversion that converts the frequency of the received signal RF_R from a high-frequency band to a baseband through a frequency signal provided by a local oscillator LO in PLL circuit 2230. For example, the second mixer MX2 may convert the RF received signal RF_R into a baseband signal through the LO signal LO.

Such frequency down-conversion may enable the RF receive signal RF_R corresponding to the baseband signal to be provided as a receive signal RX to the second analog baseband filter ABF2, which may filter the receive signal RX corresponding to the baseband signal and provide the filtered receive signal RX to the modem 2100.

For reference, the wireless communication device 2000 may transmit a transmit signal through a plurality of frequency bands using carrier aggregation (CA) technology. For example, the wireless communication device 2000 may include a plurality of power amplifiers PA for power-amplifying a plurality of RF input signals RF_IN corresponding to a plurality of carriers, respectively. In some example embodiments, only one power amplifier PA is illustrated as an example for brevity.

The PLL circuit 2230 and the lock detector 2240 may be configured or operate according to the above-described some example embodiments (FIGS. 1 to 12). The PLL circuit 2230 may perform phase locking on the reference clock and the target clock and provide the target clock according to phase locking as an LO signal LO to the first mixer MX1 and the second mixer MX2.

The lock detector 2240 may obtain a lock detection signal LD indicating whether the PLL circuit 2230 is locked, and provide the lock detection signal LD to the digital processing circuit. According to the some example embodiments, the lock detector 2240 may delay the reference clock and the target clock based on digital codes, and determine whether the PLL circuit 2230 is locked, based on the delayed clocks. The lock detector 2240 may calibrate the digital code, delaying the reference clock, to reduce the offset caused by nonlinearity or PVT due to elements in the wireless communication device including the PLL circuit 2230. Accordingly, the lock detection may be performed more accurately.

The digital processing circuit 2110 may receive the lock detection signal LD from the lock detector 2240. When the lock detection signal LD is indicated to be locked (for example, the lock detection signal LD is high), the digital processing circuit 2110 may process the transmit signal TX and/or provide the processed transmit signal TX to the RF chip 2200. Alternatively, the digital processing circuit 2110 may monitor the frequency synchronization status based on the lock detection signal LD, and perform communication timing control and/or resynchronization.

The duplexer 2300 may be connected to the antenna ANT to separate a transmit frequency and a receive frequency. For example, the duplexer 2300 may separate the RF output signal RF_OUT, provided from the power amplifier PA, for each frequency band and provide the separated RF output signal RF_OUT to a corresponding antenna ANT. The duplexer 2300 may provide an external signal, received from the antenna ANT, to the LNA 2220 included in the receive circuit RXC of the RF chip 2200. For example, the duplexer 2300 may include a front end module with integrated duplexer (FEMiD).

For example, the wireless communication device 2000 may include a switch structure configured to separate a transmit frequency and a receive frequency instead of the duplexer 2300. The wireless communication device 2000 may include a structure including a duplexer 2300 and a switch to separate a transmit frequency and a receive frequency. For brevity, some example embodiments such as shown in FIG. 13 have been described in which the duplexer 2300 that is configured to separate a transmit frequency and a receive frequency is provided in the wireless communication device 2000.

The power modulator 2400 may generate a dynamically level-varying modulated output voltage based on the analog envelope signal A_ENV and the average power signal D_REF, and may provide the output voltage as a power supply voltage for the power amplifier PA.

For example, the power modulator 2400 may receive the average power signal D_REF and the analog envelope signal A_ENV from the modem 2100. The power modulator 2400 may operate in one of an ET (envelope tracking) mode and an APT (average power tracking) mode based on the received average power signal D_REF and analog envelope signal A_ENV to generate a dynamically varying output voltage. The power modulator 2400 may supply the generated output voltage to the power amplifier PA as a power supply voltage.

For example, when a fixed level of power supply voltage is applied to the power amplifier PA, the power efficiency of the power amplifier PA may be degraded. Accordingly, to achieve efficient power management of the power amplifier PA, the power modulator 2400 may modulate an input voltage (for example, power supplied from a battery) based on at least one of the analog envelope signal A_ENV and the average power signal D_REF, and provide the modulated voltage to the power amplifier PA as a power supply voltage.

The antenna ANT may transmit the RF output signal RF_OUT, frequency-separated by the duplexer 2300, to an external entity or provide the RF received signal RF_R, received from an external entity, to the duplexer 2300. For example, the antenna ANT may include an array antenna, but some example embodiments are not limited thereto.

For example, the modem 2100, the RF chip 2200, the power amplifier PA, the duplexer 2300, and the power modulator 2400 may be individually implemented as an integrated circuit IC, a chip, or a module. The modem 2100, the RF chip 2200, the power amplifier PA, the duplexer 2300, and the power modulator 2400 may be mounted together on a printed circuit board (PCB). However, some example embodiments are not limited thereto, and in some other example embodiments, at least some of the modem 2100, RF chip 2200, duplexer 2300, and power modulator 2400 may be implemented as a single communication chip.

Furthermore, the wireless communication device 2000 illustrated in FIG. 13 may be included in a wireless communication system using a cellular network such as 5G, long-term evolution (LTE), or the like, or may be included in a wireless local area network (WLAN) system or any other wireless communication system. For example, the configuration of the wireless communication device 2000 illustrated in FIG. 13 may be only an example. Some example embodiments are not limited thereto, and the wireless communication device 2000 illustrated in FIG. 13 may be configured in various ways based on communication protocols or communication schemes.

As set forth above, according to some example embodiments, a lock detector configured to improve the accuracy of lock detection, an RF chip including the lock detector, and a method of determining lock detection in a lock detector may be provided.

Some embodiments of the inventive concepts may further provide an electronic device that includes a modem that digitally processes a first signal to provide a first baseband signal based on a lock detection signal, and converts the first baseband signal into a first transmit signal that is an analog signal; a transmit circuit that frequency up-converts the first transmit signal based on a local oscillator signal to provide a first RF signal; a duplexer circuit that provides the first RF signal to an antenna for transmission; a phase locked loop (PLL) that detects a phase difference between a reference clock and a target clock and adjusts a frequency of the target clock to reduce the phase difference, and provides the target clock to the transmit circuit as the local oscillator signal; and a lock detector that provides a first delayed clock by delaying the reference clock based on a first digital code, provides a second delayed clock by delaying the target clock based on a second digital code, provides an error signal indicating a phase relationship between the first delayed clock and the second delayed clock, calibrates the first digital code to reduce a phase difference between the first delayed clock and the second delayed clock based on the error signal, and generates the lock detection signal indicating whether the first delayed clock and the second delayed clock are within a set lock detection range.

In some example embodiments, the duplexer provides a second RF signal based on an external signal received by the antenna, and the electronic device further includes a receive circuit that frequency down-converts the second RF signal based on the local oscillator signal to provide a first receive signal that is a baseband signal to the modem.

In some example embodiments, the modem converts the first receive signal into a first digital signal and digitally processes the first digital signal based on the lock detection signal.

In some example embodiments, the lock detector includes a logic circuit that provides a select signal having a logical high state based on a phase of the first delayed clock leading a phase of the second delayed clock, and provides the select signal having a logical low state based on the phase of the first delayed clock lagging behind the phase of the second delayed clock; and a multiplexer that selects a sign of the error signal as positive or negative based on the select signal.

In some example embodiments, the logic circuit includes a first flip-flop that samples the first delayed clock based on the second delayed clock; a first inverter that inverts the phase of the second delayed clock; a second flip-flop that samples an output of the first flip-flop based on an output of the first inverter; a second inverter that inverts a phase of the output of the first inverter; and a third flip-flop that samples an output of the second flip-flop based on an output of the second inverter. An output of the third flip-flop is provided as the select signal.

In some example embodiments, the lock detector calibrates the first digital code based on a least mean square (LMS) algorithm, and based on the LMS algorithm, the lock detector determines a sign of a weight defined for the first digital code as positive or negative based on a sign of the error signal, and reduces an error defined for the first digital code based on the weight.

In some example embodiments, the lock detector performs sigma-delta modulation on the first digital code calibrated based on the LMS algorithm, and based on the sigma-delta modulation, the lock detection circuit quantizes a plurality of bits included in the first digital code that is calibrated into remaining bits excluding at least one bit corresponding to fractional value information.

In some example embodiments, the transmit circuit, the receive circuit, the phase locked loop and the lock detector are disposed on an RF chip.

In some example embodiments, the set lock detection range is greater than or equal to a resolution value of the first digital code.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While some various example embodiments have been shown and described above, it will be apparent to those skilled in the art that modifications and variations could be made without departing from the scope of the present inventive concepts as defined by the appended claims.

What is claimed is:

1. A lock detector comprising:
a first digital-to-time converter (DTC) configured to delay a reference clock based on a first digital code to provide a first delayed clock;
a second DTC configured to delay a target clock based on a second digital code to provide a second delayed clock;
a phase difference detection circuit configured to obtain an error signal indicating a phase relationship between the first delayed clock and the second delayed clock;
a calibration circuit configured to calibrate the first digital code to reduce a phase difference between the first delayed clock and the second delayed clock based on the error signal; and
a lock detection circuit configured to provide a lock detection signal indicating whether the first delayed clock and the second delayed clock are within a set lock detection range.

2. The lock detector of claim 1, wherein the phase difference detection circuit comprises:
a logic circuit configured to provide a select signal having a logical high state based on a phase of the first delayed clock leading a phase of the second delayed clock, and provide the select signal having a logical low state based on the phase of the first delayed clock lagging behind the phase of the second delayed clock; and
a multiplexer configured to select a sign of the error signal as positive or negative based on the select signal.

3. The lock detector of claim 2, wherein the logic circuit comprises:
a first flip-flop configured to sample the first delayed clock based on the second delayed clock, and
the select signal is based on an output of the first flip-flop.

4. The lock detector of claim 2, wherein the logic circuit comprises:
a first flip-flop configured to sample the first delayed clock based on the second delayed clock;
a first inverter configured to invert a phase of the second delayed clock;
a second flip-flop configured to sample an output of the first flip-flop based on an output of the first inverter;
a second inverter configured to invert a phase of the output of the first inverter; and
a third flip-flop configured to sample an output of the second flip-flop based on an output of the second inverter,
wherein an output of the third flip-flop is provided as the select signal.

5. The lock detector of claim 1, wherein
the calibration circuit is configured to calibrate the first digital code based on a least mean square (LMS) algorithm.

6. The lock detector of claim 5, wherein
based on the LMS algorithm, the calibration circuit is configured to determine a sign of a weight defined for the first digital code as positive or negative based on a sign of the error signal, and reduce an error defined for the first digital code based on the weight.

7. The lock detector of claim 5, wherein
the calibration circuit is configured to perform sigma-delta modulation on the first digital code calibrated based on the LMS algorithm.

8. The lock detector of claim 7, wherein
based on the sigma-delta modulation, the calibration circuit is configured to quantize a plurality of bits included in the first digital code that is calibrated into remaining bits excluding at least one bit corresponding to fractional value information.

9. The lock detector of claim 1, wherein the lock detection circuit comprises:
a third DTC configured to delay the first delayed clock based on a third digital code to provide a third delayed clock;
a fourth DTC configured to delay the second delayed clock based on a fourth digital code to provide a fourth delayed clock;
a first flip-flop configured to sample the second delayed clock based on the third delayed clock;
a second flip-flop configured to sample the first delayed clock based on the fourth delayed clock; and
an AND gate configured to output the lock detection signal based on an AND operation on an output of the first flip-flop and an output of the second flip-flop.

10. The lock detector of claim 9, wherein
the set lock detection range is set to be greater than or equal to a resolution value of the first digital code.

11. A radio-frequency (RF) chip comprising:
a phase locked loop (PLL) circuit configured to detect a phase difference between a reference clock and a target clock, and adjust a frequency of the target clock to reduce the phase difference; and
a lock detector configured to provide a first delayed clock by delaying the reference clock based on a first digital code, provide a second delayed clock by delaying the target clock based on a second digital code, provide an error signal indicating a phase relationship between the first delayed clock and the second delayed clock, calibrate the first digital code to reduce a phase difference between the first delayed clock and the second delayed clock based on the error signal, and provide a lock detection signal indicating whether the first delayed clock and the second delayed clock are within a set lock detection range.

12. The RF chip of claim 11, wherein the PLL circuit comprises:
a phase detection circuit configured to provide a voltage control signal corresponding to the phase difference between the reference clock and the target clock;
a charge pump circuit configured to adjust a voltage at a control node based on the voltage control signal;
a loop filter coupled to the control node;
a voltage-controlled oscillator coupled to the control node, the voltage-controlled oscillator configured to provide an oscillation signal based on the voltage at the control node; and
a divider circuit configured to provide the target clock based on dividing a frequency of the oscillation signal.

13. The RF chip of claim 11, wherein the lock detector comprises:
a logic circuit configured to provide a select signal having a logical high based on a phase of the first delayed clock leading a phase of the second delayed clock, and provide the select signal having a logical low state based on the phase of the first delayed clock lagging behind the phase of the second delayed clock; and
a multiplexer configured to select a sign of the error signal as positive or negative based on the select signal.

14. The RF chip of claim 13, wherein the logic circuit comprises:
a first flip-flop configured to sample the first delayed clock based on the second delayed clock;
a first inverter configured to invert a phase of the second delayed clock;
a second flip-flop configured to sample an output of the first flip-flop based on an output of the first inverter;
a second inverter configured to invert a phase of the output of the first inverter; and
a third flip-flop configured to sample an output of the second flip-flop based on an output of the second inverter,
wherein an output of the third flip-flop is provided as the select signal.

15. The RF chip of claim 11, wherein
the lock detector is configured to calibrate the first digital code based on a least mean square (LMS) algorithm, and
based on the LMS algorithm, the lock detector is configured to determine a sign of a weight defined for the first digital code as positive or negative based on a sign of the error signal, and reduce an error defined for the first digital code based on the weight.

16. The RF chip of claim 15, wherein
the lock detector is configured to perform sigma-delta modulation on the first digital code calibrated based on the LMS algorithm, and
based on the sigma-delta modulation, the lock detector is configured to quantize a plurality of bits included in the first digital code that is calibrated into remaining bits excluding at least one bit corresponding to fractional value information.

17. A method of determining lock detection of a lock detector, the method comprising:
delaying a reference clock based on a first digital code to provide a first delayed clock;
delaying a target clock based on a second digital code to provide a second delayed clock;
generating an error signal indicating a phase relationship between the first delayed clock and the second delayed clock;
calibrating the first digital code to reduce a phase difference between the first delayed clock and the second delayed clock based on the error signal; and
generating a lock detection signal indicating whether the first delayed clock and the second delayed clock are within a set lock detection range.

18. The method of claim 17, wherein
the calibrating the first digital code comprises calibrating the first digital code based on a least mean square (LMS) algorithm, and
the LMS algorithm determines a sign of a weight defined for the first digital code as positive or negative based on a sign of the error signal, and reduces an error defined for the first digital code based on the weight.

19. The method of claim 18, wherein
the calibrating the first digital code further comprises performing sigma-delta modulation on the first digital code calibrated through the LMS algorithm, and
the sigma-delta modulation quantizes a plurality of bits included in the first digital code that is calibrated into remaining bits excluding at least one bit corresponding to fractional value information.

20. The method of claim 17, wherein
the set lock detection range is greater than or equal to a resolution value of the first digital code.
